(19) United States
(12) Patent Application Publication
(10) Pub. No.: US 2026/0015711 A1
(43) Pub. Date: Jan. 15, 2026

(54) PROCESS TO DEPOSIT QUANTIZED NANO LAYERS BY MAGNETRON SPUTTERING

(71) Applicant: EVATEC AG, Trübbach (CH)

(72) Inventors: Silvia SCHWYN THÖNY, Wangs (CH); Manuel Ilias BÄRTSCHI, Vaduz (LI); Manuel BASELGIA, Chur (CH); Marietta Christina BATZER, Sargans (CH)

(21) Appl. No.: 19/112,056

(22) PCT Filed: Aug. 17, 2023
(86) PCT No.: PCT/EP2023/072712

§ 371 Date: Mar. 14, 2025

(30) Foreign Application Priority Data
Sep. 16, 2022 (CH) CH001079/2022

(51) Int. Cl. C23C 14/35; C23C 14/50; C23C 14/54; G02B 1/115; H01J 37/32; H01J 37/34

(52) U.S. Cl. CPC C23C 14/35; C23C 14/54; G02B 1/115; H01J 37/32091; H01J 37/3244; H01J 37/32715; H01J 37/32899; H01J 37/3423; H01J 37/3426; H01J 37/3452; C23C 14/505; H01J 2237/20214; H01J 2237/24585; H01J 2237/332

(57) ABSTRACT

To deposit nanolaminates on a substrate, the substrate is mounted in a vacuum recipient on a substrate support in a peripheral region of a holder. The recipient comprises a sputter station with a sputtering target and a plasma treatment station with a plasma source, wherein the sputtering target and the plasma source are directed to different sections of the holder. A sputtering gas is introduced into the recipient, a reactive gas is introduced into the sputter station and the plasma treatment station, a magnetron discharge is ignited in the sputter station, and a plasma is ignited in the plasma treatment station. By rotation of the holder, the substrate is successively exposed to the magnetron discharge to deposit a well layer of high refractive index material having a layer thickness between 0.1 nm and 6 nm and to the plasma to produce a layer of low refractive index material.

### TECHNICAL FIELD OF THE INVENTION

The current invention relates to a sputtering process to deposit quantized nanolaminates (QNLs) on a surface of a substrate according to claim 1, to an optical device according to claim 23, and to a process system to deposit such nanolaminates according to claim 30.

### DESCRIPTION OF THE RELATED ART

Optical interference coatings such as anti-reflection, mirror or filter coatings are based on stacks of materials with at least 2 different refractive indices n. The interference effect is stronger the larger the difference in refractive index of the materials is. As a consequence, layer stacks using materials with high refractive index difference require a smaller number of individual layers and thus less overall thickness than stacks with a low difference in index. In addition to the refractive index the materials have to fulfill another requirement, namely that they are transparent with negligible losses in the wavelength range of interest.

However, it is known since long that in dielectric materials the refractive index and absorption edge are linked. Materials with high refractive index have their absorption edge at a high wavelength, while low refractive index materials have the absorption edge at a lower wavelength.

An approach to decouple refractive index and absorption edge is glancing angle deposition in which a columnar film structure is formed, which reduces the effective refractive index. Thus, interference effects will occur between continuous layers and layers with columnar structure of one and the same material. This opens up interesting effects such as higher laser damage resistance due to the absence of interfaces between different materials, but with the drawback of increased sensitivity to environmental conditions.

A recent concept to overcome the connection between the two characteristics are Quantized NanoLaminates (QNLs), which were first proposed by Jupe et al in 2019. In this concept thin layers of high and low refractive index with a thickness in the nanometer range or below are stacked. These layers are called well layers for the high index material, respectively barrier layers for the low index material. The limited structure size leads to a change of the energy gap, which can be adjusted by the physical thickness of the materials, whereas the ratio of the materials determines the effective refractive index of the QNL.

In optical interference coatings, the decoupling of band gap and refractive index potentially offers the advantage of using a material combination to design a material of any specific refraction index instead of searching through the limited number of known materials. As an example, in the UV range the band gap of Ta₂O₅ can be pushed towards shorter wavelength and can thus replace the use HfO₂. This is desirable since hafnium targets are expensive and because HfO₂ has a tendency to grow polycrystalline forming grain boundaries, which can cause losses by straylight.

Another example has been detailed by Henning et al. in “Manufacturing of Si-based hybrid metamaterials for increasing the refractive index in interference coatings”, Md.1, OIC 2022 XX, it is explained that a combination of amorphous silicon and SiO₂ has the potential to be transparent even in the visible wavelength range with an effective refractive index higher than 2.7. Such a material would offer great advantage over the well-known TiO₂, which is the material with the highest refractive index being transparent in the visible wavelength range. However, so far, no experimental evidence of the effect could be shown.

Up to now the QNL effect has been demonstrated experimentally only for Atomic Layer Deposition (ALD) and ion beam sputtering (IBS) coatings, by Steinecke et al. in “Quantizing nanolaminates as versatile materials for optical interference coating”, J. optical Society of America, Vol 59, No. 5/10 Feb. 2020. Even though both alternative methods lead to good results, they have their drawbacks with regards to volume production. ALD has low growth rates, since only one atomic layer is deposited per coating cycle, whereas in IBS a zone target needs to be mechanically translated from one material of the nanolaminate to the other which also limits the deposition rate essentially. In the same paper it is also explicitly mentioned that several attempts to deposit such layers by RF-puttering could deposit reliably only with layer thicknesses of above 5 nm, which is too thick to show a quantizing effect.

### SUMMARY OF THE INVENTION

It is a task of the present invention to solve the problems of the prior art and to provide an alternative but industrially usable process for the deposition of QNL films as well as a corresponding vacuum process tool for the production of such layers. In addition, it is a task to provide a new species of optical devices using QNL films as produced by the respective process.

These tasks are solved by a process with the features of claim 1, by a vacuum process system to deposit such nanolaminates according to claim 30, and an optical device according to claim 23. Further embodiments of the inventive process, process system and device are defined by the features of the respectively depending claims.

According to the invention a process to deposit so called quantized nanolaminates (QNLs) on a surface of a flat substrate comprises the following steps:
mounting the substrate(s) in a vacuum process system on a substrate support in a peripheral region (R) of a holder, the holder being rotatably mounted round its central axis B, the recipient comprising at least one magnetron sputter station with a sputtering target mounted to a sputter source and spaced apart from the magnetron sputter station at least one plasma treatment station with a further plasma source, the sputtering target and the plasma source both directed with their effect to a different section of the peripheral region (R) in each case
pumping down the recipient,
rotating the holder at a constant speed round a central axis,
introducing a sputtering gas into the recipient, e.g., in next proximity or directly into the sputter station, which can be realized by a gas ring or another type of circumferential gas supply, e.g., a slot like gas supply, which both can be mounted round the opening of the sputter station or within the sputter station, and
introducing a reactive gas directly into at least one of the sputter station or the plasma station, whereat similar or the same types of gas ducts can be chosen,
igniting a magnetron discharge in the sputter station and setting a magnetron power level (Pₘ), and
igniting a treatment discharge in the plasma treatment station and setting a plasma power level (Pₚ) of the plasma source,
exposing the substrate(s) successively and preferably repeatedly by the rotation of the holder
   to the magnetron discharge to deposit a layer Lₕ of a high refractive index material, and
   to the treatment discharge to produce a layer Li of a low refractive index material,
      whereat the rotation speed of the holder and the magnetron power level (Pₘ) is set so, that the layer thickness dₕ (sometimes also d_{well} or tₕ) of a well layer Lₕ of the high refractive material, which may have an index of refraction above 1.65, is:

$$0. 1 \leq {d}_{h} \leq 5 nm ( see Steinecke ) , e . g . , 0.1 \leq {d}_{h} \leq 4. nm ,$$

$$and especially e . g . 0.1 \leq {d}_{h} \leq 3 nm .$$

In an embodiment of the present invention the plasma power level (Pₚ) is set so that the layer thickness dₗ (sometimes also d_{barrier} or tₗ) of a barrier layer Lₗ of the low refractive material, which may have an index of refraction at or below 1.65:

$$0. 1 \leq {d}_{1} \leq 30 nm e . g . , 0.1 \leq {d}_{1} \leq 20 nm ,$$

$$and especially 0.5 \leq {d}_{1} \leq 10 nm .$$

In an embodiment of the present invention the target may be one of Al, Si, Ti, Zr, Hf, Nb, Ta, Ge, respective oxides, nitrides or a mixture thereof, e.g., AlTi, TiZr, NbTa, or else, and respective oxides or nitrides. High index materials deposited with such targets can be amorphous silicon (a-Si), the oxides of the transition metals like TiO₂, ZrO₂, HfO₂, Nb₂O₅, Ta₂O₅, or respective mixtures, but as far as SiO₂ is produced in the plasma station as the low index material also Al₂O₃ or Si₃N₄ can be deposited in the sputter station as high index materials.

In an embodiment of the present invention the plasma station may comprise a plasma source, which here is not a magnetron sputtering source, and the reactive gas is introduced directly into the plasma station.

In an embodiment where a plasma station which is not a magnetron sputtering source is used to produce the second index layer, e.g., the low index layer, the target of the sputter station which is run as an example with noble gas only, the sputter station can be set without further control measures to a power level and stays constant. At the same time, also a power of the plasma source can be set to a constant level and a plasma gas parameter in the plasma station, which may be, e.g., an overall pressure, a reactive gas pressure, however preferably a reactive gas flow, can be controlled with a plasma emission monitor (PEM) by the intensity of at least one defined line of the gas-plasma emission.

When such a plasma source is used, e.g., to produce the low index material layer, the target may be silicon and the sputtering gas, which may be a noble gas, can be introduced, e.g., in next proximity or directly into the sputter station to deposit a high index a-Si layer on the surface of a substrate passing the opening of the sputter station. The reactive gas of the plasma source can then be oxygen and be introduced directly into the plasma station to oxidize a surface region of the a-Si layer, which has been deposited immediately before, when the substrate passes the plasma outlet opening of the plasma station. Introducing the reactive gas directly to the plasma source hereby helps to avoid disturbing the sputtering process with the plasma station.

More specifically, the following parameters may be chosen for a combination of a sputter station with a target of Si containing material (e.g., essentially pure Silicon) and a plasma station when alternating high- and low-index layers (e.g.: a-Si/SiO₂) should be deposited:
Power sputtering source (P_{Sput}): 0.5-10 kW, e.g., 1-7 kW;
Gas flow sputter source (f_{Sput}): 10-300 sccm, e.g., 30-250 sccm;
Power plasma source (P_{PSC}): 0.1-5 kW, e.g., 0.25-3 kW;
Gasflow plasma source (f_{PSC}): 1-50 sccm, e.g., 2-30 sccm;
Total pressure resulting of both gasflows: 1e⁻³-2e⁻² mbar.

In this case the total pressure can be set relatively high with reference to known sputter processes and so should be the relation of sputter gas to reactive gas (fₛₚᵤₜ/f_{PSC}) from about 5 to 30, respectively 6 to 15 to avoid target poisoning of the Si-target.

When, as an specific example, an a-Si layer of 0.5 nm has been deposited at a rotational speed of 3 sec/pass, a target power of 2.5 kW, and an Ar-flow of 200 sccm, a surface near region of 0.25 nm of the a-Si layer can be oxidized to SiO₂ by applying the following parameters to the plasma source: P_{PSC}=250 W and f_{PSC}=2 sccm O₂, which results in a total pressure of 6e⁻³ mbar. Therewith, a 0.25 nm a-Si layer followed by a 0.25 nm SiO₂ layer could be produced on an Evatec Clusterline BPM magnetron sputter deposition system. Further examples will follow below under detailed description of the invention.

In a further embodiment of the present invention the plasma treatment station is a further magnetron sputter station comprising a further target. The further target may be one of Si, SiO₂, Si₃N₄, Al, Al₂O₃, or AlN to deposit the low index material. With that embodiment the sputtering gas can be introduced to the sputter station and the further sputter station via separate gas ducts.

A power can be set with the target and/or the further target. At the same time or delayed a reactive gas can be introduced, e.g. by the same or a different gas inlet as the sputter gas, and a reactive gas parameter in the sputter station and/or the further sputter station can be controlled with a plasma emission monitor (PEM) by the intensity of at least one defined line of the target plasma emission in a transition region, respectively transition mode of a reactive sputtering process, where the target surface is neither pure metallic nor completely poisoned, e.g. oxidized, by the reactive gas, which makes any other process control but with PEM difficult. Therewith completely reacted layers can be deposited on the substrate without poisoning the target surface completely which allows to maintain a high deposition rate and to avoid process instabilities.

Thereby as an example the following process parameters may be chosen for a combination of two sputter stations alone (comprising the sputter and the further sputter station) when alternating high- and low-index layers should be deposited:

Sputtering source 1 to deposit high index layer Lₕ:
Power P_{Sput1}: 0.5-10 kW, e.g., 1-8 kW;
Target material: Al, Si, Ti, Zr, Hf, Nb, Ta, Ge, respective oxides, nitrides or a mixture thereof.
Deposition atmosphere: Usually a mixture of sputter gas (any noble gas) and a reactive gas like oxygen or nitrogen. At least the reactive gas will be supplied in in next proximity or directly into the sputter station. Gas flows applied can be: 10≤f_{noble}≤200 sccm; 1≤f_{react}≤100 sccm. For the deposition of an a-Si layer however a (pure) noble gas atmosphere should be used: 10≤f_{noble}≤300 sccm, see also above.

Sputtering source 2 (further sputtering source) to deposit low index layer Lₗ:
Power P_{Sput2}: 0.5-10 kW, e.g., 1-8 kW;
Target material: Al, Si, respective oxides, nitrides or a mixture thereof.
Deposition atmosphere: Usually a mixture of sputter gas (any noble gas) and a reactive gas like nitrogen, preferably however oxygen. At least the reactive gas will be supplied in in next proximity or directly into the sputter station. Gas flows applied can be: 10≤f_{noble}≤200 sccm; 1≤f_{react}≤100 sccm.

Sputtering gases in any embodiment of the invention can be any noble gases, e.g., at least one of Argon, Krypton, Neon, Xenon or any mixture thereof.

In any embodiment of the invention whereat reactive gases are used the reactive gas and/or a further reactive gas, which can be different or the same, can be introduced directly into the sputter station and directly into the plasma station or alternatively or in addition to the further sputter station, e.g. by separate gas ducts to the respective two, three, four or more stations. The reactive gas and/or the further reactive gas can be oxygen or nitrogen.

In any embodiment of the invention a process shutter may be provided with the sputter station and/or the further sputter station, whereat the process shutter can be closed during an ignition phase of the respective sputter station until the sputtering process has been stabilized and the layer deposition can start, whereon the shutter is opened during a deposition phase of the respective layer.

In an embodiment of the invention whereat n layers Lₕ of the high refractive material and n or n±1 layers Li of the low refractive material are deposited alternatingly as a stack on at least one surface of the flat substrate, the number n of the respective layers in the stack can be at least one for every layer Lₕ and Lₗ and: 1≤n≤10,000 where a number from 2≤n≤2,000 is the most practicable.

An example for the utmost thinnest layer combination as deposited is the following combination: 0.1 nm Ta₂O₅/0.2 nm SiO₂. Thick nanolaminates of 500 nm can have 1,666 layers of each the high and the low index layer alternating each other. A typical thickness of an interference filter can be from 1 to 300 nm. Further examples will follow below under detailed description of the invention.

In a further embodiment of the present invention being combinable with any other embodiment between the stack and the glass substrate and/or between the stack and the atmosphere at least one further layer or coating which may consist of several layers can be provided, respectively deposited. Such coatings can be exemplarily, an adhesion layer/coating towards the substrate, a scratch resistant layer/coating towards atmosphere, an AR or IR-reflecting coating.

With stacks of alternating layers of high and low index material an overall refractive index reflects the percentage of the respective high and low refractive materials used for the well and barrier layers of the stack n_{SUM}²=x*nₕ²+y*nₗ², where 0≤x≤1, 0≤y≤1, and x+y=1. In an inventive embodiment which may apply to any embodiment of the invention, unless there is a contradiction, a transmission edge T of the stack, and there with the respective absorbance edge (T-R) is shifted toward a lower wavelength with shrinking well thickness. That means that for layer stacks of the same high and low index material and the same percentage of the high index material to the low index material, which may e.g. be expressed by the percentage of the total (optical) thickness of the layers of high index material (d_{h_tot}=n*dₕ) to the layers of low index material (d_{l_tot}=(n±1)*dₗ), but a different well thickness is applied the respective shift of transmission edge T can be expressed for combinations of oxidic and/or nitride high and low index materials, e.g. as mentioned above, as following:

$$Δ {T}_{50} = {T}_{50 \_ THICK} - {T}_{50 \_ THINN} and$$

$$2 \leq Δ {T}_{50} \leq 60 nm , e . g . , 5 \leq Δ {T}_{50} \leq 40 nm .$$

Due to the high refractive index of a-Si, the material combination a-Si/SiO2 exhibits a larger shift of transmission edge T:

$$20 \leq Δ {T}_{50} \leq 600 nm , e . g . , 50 \leq Δ {T}_{50} \leq 400 nm .$$

Hereby ΔT₅₀ is the difference of transmittance T_{50_THICK}−T_{50_THINN} at 50%, where the transmittance of a layer stack having a thickness of the well layer(s) d_{h_THICK}≥5 nm, e.g., 5 to 50 nm, and the Transmittance T_{50_THINN} of a layer stack produced by the inventive process having thin well layer(s) d_{h_THIN}≤3 nm e.g. 3 to 0.1 nm, is compared. Where at least for coatings deposited with the inventive process the thickness of all well layers preferably equals to the same value dₕ, and the thickness of all barrier layers preferably equals to the same value dₗ, which values can and usually will be different with dₕ≤dₗ or dₕ<dₗ.

In a further inventive embodiment, which can be combined with any other inventive embodiment, unless there is a contradiction the gap energy E_{gap} between a free ground state and a higher conduction state grows with thinner well layers Lₕ by an amount ΔE_{gap}=E_{gap_THINN}−E_{gap_THICK} where:

$$0.01 \leq Δ {E}_{gap} \leq 0.8 eV , e . g . , 0.02 \leq Δ {E}_{gap} \leq 0.4 eV ,$$

for combinations of oxidic and/or nitride high and low index materials, e.g., as mentioned above.

For the material combination a-Si/SiO₂ the following ranges have been determined:

$$0.01 \leq Δ {E}_{gap} \leq 2 eV , e . g . , 0.02 \leq Δ {E}_{gap} \leq 1.5 eV ,$$

whereat ΔE_{gap} is the difference of the E_{gap_THINN} of layers produced by the inventive process having thin well layer(s) d_{h_THIN}≤3 nm e.g., 3 to 0.1 nm and the E_{gap_THICK} of layer stacks having a thickness of the well layer(s) d_{h_THICK}≥5 nm, e.g., 5 to 50 nm. Respective lower energy gaps here stand for a well layer thickness dₕ of about 2 to 1.5 nm, and the higher energy gap stands for a well layer thickness dh of about 0.1 to 0.5 nm. The absolute value within that range may also depend on the respective low and high refractive material pairing.

In a further inventive embodiment which can be combined with any other inventive embodiment, unless there is a contradiction, the holder is a turntable holder, the peripheral region (R) is defined by an outer circular ring with substrate holders arranged along the ring, e.g., with their respective geometric centres along a middle diameter of the ring, on at least one main surface of the disc-like holder, i.e., on the upper or the lower surface of the turntable holder. There the flat substrates are mounted on or in the substrate supports in a plane parallel to the turntable plane. The latter can be vertically with a turntable holder having a horizontal rotational axis B, however a horizontal turntable holder, respective turntable holder plane P having a vertical rotational axis B and substrates positioned horizontally is preferred. Details of a respective turntable holder see examples and Figures below.

In a further inventive embodiment which can be combined with any other inventive embodiment, unless there is a contradiction, the holder is a cylinder or a cylinder-like multifaceted holder, the peripheral region (R) is defined by the cylindrical or multifaceted surface of the holder and substrate supports are arranged with their centres along at least one diameter of constant height on the cylindrical or multifaceted surface of the holder. Flat substrates can be mounted in or on the cylindrical or multifaceted surface, in a plane essentially in parallel to the cylindrical or multifaceted surface. Essentially in parallel hereby means tangentially with the cylindrical surface, usually with the substrate centre as a contact point or the point nearest to the cylindrical diameter of the holder which depends on the type of support. With reference to the multifaceted surface, it means in parallel to a facet of the faceted surface. In both cases, due to the support geometry, substrate positions some millimetres above or below the respective holder surface or holder diameter are comprised as man of the art will immediately understand. Axis B of the holder can be horizontally, however in this case a vertical substrate position of the substrates on a cylindrical holder with vertical axis B is preferred.

In a further inventive embodiment, which can be combined with any other inventive embodiment, unless there is a contradiction, the substrate can be a wafer, e.g., a silicon or a glass wafer.

In a further embodiment of the invention the substrate can be a wafer and the peripheral region (R) is in a radial distant of 535±60 mm from the central axis B and the constant speed is set from 30 to 0.5 seconds per rotation, e.g., from 2 to 20 s/pas which equals to seconds per rotation. With such a configuration as an examples 16 wafers up to 200 mm diameter can be coated at the same time (or 15 wafers and a dummy wafer).

For any disc like substrates like wafers, disk like circular targets with a respective essentially cylindrical magnetron source or respective linear sputter sources with linear targets can be used, whereat the diameter or circumference of the active zone, also called the racetrack should project laterally the substrate to provide an even coating quality and thickness over the whole substrate surface. To provide best target utilisation with circular targets, the target or the magnetic system may be rotated. In case of a turntable holder, as described above and with the detailed description in the following, however, static asymmetric magnet systems can be beneficial to compensate for different deposition rates due to the different radial speed of outer and inner areas of the substrate surface, as descried in detail in WO 2017042123 A1 of the same applicant with FIGS. 4 and 2 and respective description. To combine an optimum coating distribution with cost efficiency the target diameter D_{T} should be essentially larger than the diameter of the wafer D_{W} to be coated, e.g., 1.4*D_{W}≤D_{T}≤1.7*D_{W} with magnet system eventually combined with a magnet or target rotation allowing an even material erosion over the whole target surface. As an example, for a 200 mm wafer the following range can be applied with good results: 280≤D_{T}≤340, especially 300≤D_{T}≤320.

The invention further comprises an optical device comprising a substrate and an optical coating deposited on at least one side of the substrate, the optical coating consisting of at least one film of high refractive material and at least one film of low refractive material, wherein at least one of the high and/or the low index material films is designed as a quantized nanolaminate (QNL) of a defined high or low overall QNL-index of refraction (n_{QNL}), whereas the QNL-film, i.e., the stack of quantized layers of high and low refractive material, comprises at least a well layer Lₕ of high refractive material and alternating to each other at least a barrier layer Lₗ of low refractive index material, whereat the layer thickness dₕ of the well layer Lₕ is:

$$0.1 \leq {d}_{h} \leq 6 nm , thereby preferably 0.1 \leq {d}_{h} \leq 4. nm ,$$

$$e . g . , 0.1 \leq {d}_{h} \leq 3 nm .$$

In a further inventive embodiment of a device which can be combined with any other inventive embodiment, unless there is a contradiction, the layer thickness dₗ of a barrier layer Lₗ of the low refractive material is:

$$0.1 \leq {d}_{1} \leq 30 nm , thereby preferably 0.1 \leq {d}_{1} \leq 20 nm ,$$

$$e . g . , 0.5 \leq {d}_{1} \leq 10 nm .$$

In a further inventive embodiment, the QNL-film defines the high refractive film of the optical coating.

The low refractive material of the low index film can be the same material as the low refractive material of the barrier layer(s) Li in the QNL-film in a further embodiment of the invention.

The number n of the respective layers in the stacked QNL-film is at least one for every layer Ln and Li and:

$$1 \leq n \leq {10}^{′} 000 , e . g . , 2 \leq n \leq {2}^{′} 0.$$

In any embodiment of the invention the device can be produced according to a process as described above.

In an embodiment of the invention the optical coating can be an interference coating, e.g., an antireflection (AR) coating (for visible or IR light). The device can be a mirror, a semi selective mirror, a filter, or a respectively coated lens. When the device is a filter, it can be a notch, a shortpass or a longpass edge filter, a beam splitter, or a polarizer.

The invention further comprises a vacuum process system to deposit so called quantized nanolaminates (QLNs) consisting of at least one well layer Ln of high index material and at least one barrier layer Lₗ of low index material, on a surface of a flat substrate, the recipient comprising:
A holder being rotatable round its central axis B with a substrate support in a peripheral region (R) of the holder,
at least one magnetron sputter station with a sputtering target mounted to a sputter source and spaced apart from the magnetron sputter station,
at least one plasma treatment station with a plasma source,
the sputtering target and the plasma source both directed with their effect to a different section of the peripheral region (R) in each case, e.g. via a respective opening of the target station and the plasma station,
a sputter gas inlet to introduce a sputtering gas into the recipient, which can preferably be arranged in next proximity or in the sputter station, e.g., round the target; therefore, the sputter gas inlet may comprise a gas ring or another type of circumferential gas supply, e.g., a slot round the opening of the sputter station or within the sputter station, and
a reactive gas inlet and/or a further reactive gas inlet to introduce a reactive gas into the recipient, whereat the reactive gas inlet can be provided at least in next proximity or in the sputter station, whereat the further reactive gas inlet is provided at least in next proximity or in the plasma station. In each case the reactive gas inlet can again be a gas ring or another type of circumferential gas supply, e.g., a slot round the opening of the plasma/sputter station or within the plasma/sputter station, e.g., round the target.

Thereby a rotation speed of the holder can be set from 30 to 0.5 seconds per rotation, e.g., from 2 to 20 seconds per rotation [s/pass], and the magnetron power level (Pₘ) can be set from 0.5-10 KW so, that a layer thickness dh of a well layer Lₕ of a high refractive material, e.g., a material having an index of refraction above or equal 1.65, can be set to:
0.1≤dₕ≤6 nm, thereby preferably 0.1≤dₕ≤4.0 nm, e.g., 0.1≤dₕ≤3 nm. Such rotation speed and magnetron power level may be set to industrial coating equipment having a holder diameter between 800 and 2000 mm and a target diameter between 280 to 450 mm to coat wafers of 200- or 300-mm diameter.

In a further inventive embodiment, which can be combined with any other inventive embodiment, unless there is a contradiction, the rotation speed of the holder and the magnetron power level (Pₘ) can be set so that the layer thickness tₗ of a barrier layer Lₗ of the low refractive material can be:

$$0.1 \leq {d}_{1} \leq 30 nm , thereby preferably 0.1 \leq {d}_{1} \leq 20 nm ,$$

$$e . g . , 0.5 \leq {d}_{1} \leq 10 nm .$$

In a further inventive embodiment, which can be combined with any other inventive embodiment, unless there is a contradiction, the plasma station comprises an inductive or a capacitively coupled plasma source and a reactive plasma gas inlet directly into the plasma station, e.g., with the further gas inlet arranged within the station. The further gas inlet can be connected with a nitrogen, preferably however with an oxygen supply.

In a further inventive embodiment, which can be combined with any other inventive embodiment, unless there is a contradiction, the plasma station is a capacitively coupled HF-plasma source. The plasma source may be an inductive plasma source, e.g., an IS300, but preferably a capacitively coupled RF plasma source, e.g., PSC303, both types of sources being available from Evatec AG, a Swiss manufacturer of vacuum and plasma equipment. Details with reference to a capacitively coupled RF plasma source which could be advantageously used with the present invention are disclosed in WO 2020/161139 of the same applicant, FIG. 2, 6-8 and respective description. Such a source comprises exclusively a first and a second capacitively coupled plasma generating electrode, the first electrode having a larger electrode surface and a second electrode having a smaller electrode surface in a vacuum recipient or in a respective plasma station of a process system respectively process system, a plasma outlet opening, and here a reactive gas inlet or feed from a reactive gas supply. The plasma outlet opening will be usually through the second electrode which may comprise at least one grid with a transparency of more than 50%. Said second electrode can be also set on a reference potential which can be ground potential. At least one of the larger and of the smaller electrode surfaces may be variable.

In addition, at least one coil arrangement may be provided in the space between said first and second electrode to generate a magnetic field. In an further embodiment of the plasma source the first electrode can be cup shaped, the inner surface thereof facing the second electrode, and a coil arrangement may be provided along the outer surface of said cup shaped first electrode generating a magnetic field with predominant directional component towards or from said second electrode. Such a coil arrangement may comprise at least two coils, independently supplied by respective current sources.

In a further embodiment of the invention the target can be a silicon target and the sputter gas inlet is connected to a noble gas supply only, e.g., to deposit a silicon layer.

In a further inventive embodiment, which can be combined with any other inventive embodiment, unless there is a contradiction, a plasma emission monitor (PEM) can be connected via an optical path of light to a plasma zone of the plasma source to control the power of the plasma source or the flow of the reactive gas. In generally all types of sputter and plasma stations where processes with reactive gases are performed can be equipped with Plasma Emission Monitors PEMs to exploit the hysteresis effects in the transition mode and assure full oxidation at a high deposition rate. These monitors can be designed as broad band and/or monochromatic optical monitors.

In a further inventive embodiment, which can be combined with any other inventive embodiment, unless there is a contradiction, the plasma treatment station is a further magnetron sputter station comprising a further target. The further target can be one of Si, SiO₂, Si₃N₄, Al, Al₂O₃, AlN, or a mixture thereof. In this case a further reactive gas inlet to the further target station can be provided.

In a further inventive embodiment, which can be combined with any other inventive embodiment, unless there is a contradiction, the target of the target station is one of Al, Si, Ti, Zr, Hf, Nb, Ta, Ge respective oxides, nitrides or a mixture thereof.

In a further inventive embodiment, which can be combined with any other inventive embodiment, unless there is a contradiction, a separate reactive gas inlet can be provided to both sputter stations, i.e., the sputter station and the further sputter station. The respective reactive gas inlets can be connected to the same or different gas supplies by separate reactive gas flow controllers each. In the same way a separate sputter gas inlet can be provided to both sputter stations with separately controllable sputter gas flow controllers. The sputter gas inlet and the reactive gas inlet can coincide within the respective chamber.

In a further inventive embodiment, which can be combined with any other inventive embodiment, unless there is a contradiction, the holder is a turntable holder having a turntable holder plane (P), the peripheral region (R) is defined by an outer circular ring with substrate holders arranged along the ring, e.g., with their respective geometric centres along a middle diameter of the ring, on at least one main surface of the turn-table holder, e.g., on the upper or the lower surface of the turntable holder, where the flat substrates are mounted on or in the substrate supports in a plane parallel to the turntable plane, which can be vertically with a turntable holder having a horizontal rotational axis B, however a horizontal turntable holder having a vertical rotational axis B and substrates positioned horizontally is preferred.

With any embodiment of a turntable holder the magnetron sputter station may comprise a circular target and a static magnet arrangement, said magnet arrangement:
being arranged in a plane (M) in parallel to plane (P); and
not being rotational symmetric around a target axis (C) running centrally through said magnet arrangement and being perpendicular to said plane (M), which is also parallel to axis B.

In a further inventive embodiment, which can be combined with any other inventive embodiment, unless there is a contradiction, a distance between the target and the turntable holder can be varied in a Z-direction, i.e., vertical to the turntable and substrate surface, according to the process needs.

In a further embodiment the magnet system can be separated along a line (K) in plane (M) intersecting perpendicularly target axis (C) into an
outer area oriented away from the centre of the turntable and one inner area towards it,
   where it is valid that the outer area is larger than the inner area. Where outer and inner refers to a distance further away or nearer to axis B.

Said magnet arrangement (11) can be symmetric or asymmetric around a symmetry axis (A) in the plane (M), whereat axis (A) is intersecting turntable's central axis (Z).

With any embodiment of a turntable holder the target can be a rotating target, being arranged rotatably round its central target axis (C), e.g., in parallel to central axis B.

In a further inventive embodiment, which can be combined with any other inventive embodiment, unless there is a contradiction, the holder is a cylinder or a cylinder-like multifaceted holder, the peripheral region (R) is defined by the cylindrical or multifaceted surface of the holder and substrate supports are arranged with their centres along at least one height diameter of the cylinder or multifaceted holder. Flat substrates are mounted hereby in or on the cylindrical or multifaceted surface, in a plane essentially in parallel to the cylindrical or multifaceted surface. Essentially in parallel hereby means tangentially with the cylindrical surface, usually with the substrate centre as a contact point to the cylinder, or in parallel to a facet of the faceted surface. In both cases, due to the support geometry, substrate positions some millimetres above or below the respective surface or geometric diameter are comprised as man of the art will immediately understand. Axis B of the holder can be horizontally, however in this case a vertical substrate position of the substrates on a cylindrical holder with vertical axis B is preferred.

With cylindric or multifaceted holders as above, usually longitudinal planar or cylindric, rotating magnetrons will be used. However, should disc like targets be used, substrate supports in a peripheral region (R) of the holder will be preferably positioned so that the centre of the substrate support and therewith the centre of a circular substrate can be aligned in one position with the target axis (C) during the holder rotation. Rotating magnets or rotating targets may in this case be provided with the magnetron to support an even target erosion.

The features of the above-mentioned embodiments of the process, device and/or recipient can be used in any combination, unless they contradict each other.

### BRIEF DESCRIPTION OF THE DRAWINGS

Embodiments of the current invention are described in more detail in the following with reference to the figures. These are for illustrative purposes only and are not to be construed as limiting. It shows:

FIG. 1 an energy/coating thickness scheme for QNLs;

FIG. 2A,B a top view and a cross section of a process system with a cylindrical substrate holder;

FIG. 3A,B a top view and a cross section of a process system with a turntable substrate holder;

FIG. 4A,B a top view and a cross section of a process system with a further turntable substrate holder;

FIG. 5 a transmittance versus wavelength diagram;

FIG. 6 Tauc-plot αhν^{1/2} [eV/m]^{1/2} versus photon energy diagram;

FIG. 7 an energy gap versus well thickness/pass;

FIG. 8 an energy gap versus well thickness diagram;

FIG. 9 an refractive index versus well thickness diagram;

FIG. 10 an energy gap versus refractive index diagram;

FIG. 11 a transmittance versus wavelength diagram;

FIG. 12 a reflectance versus wavelength diagram;

FIG. 13 an inventive optical device;

FIG. 14 Mirrors: transmittance spectra;

FIG. 15 Mirrors: reflectance spectra;

FIG. 16 a transmittance versus wavelength diagram;

FIG. 17 a total thickness versus table rotation diagram;

FIG. 18 a d_{SiO2}/pass versus d_{a-Si}/pass diagram;

FIG. 19a, b transmittance spectra;

FIG. 20 Tauc-plot αhν^{1/2} [eV/m]^{1/2} versus photon energy diagram;

FIG. 21 an E_{gap} versus d_{a-Si}/pass diagram;

FIG. 22 an E_{gap} versus oxygen flow diagram;

FIG. 23 LP filter: transmittance versus wavelength diagram.

### DETAILED DESCRIPTION OF THE INVENTION

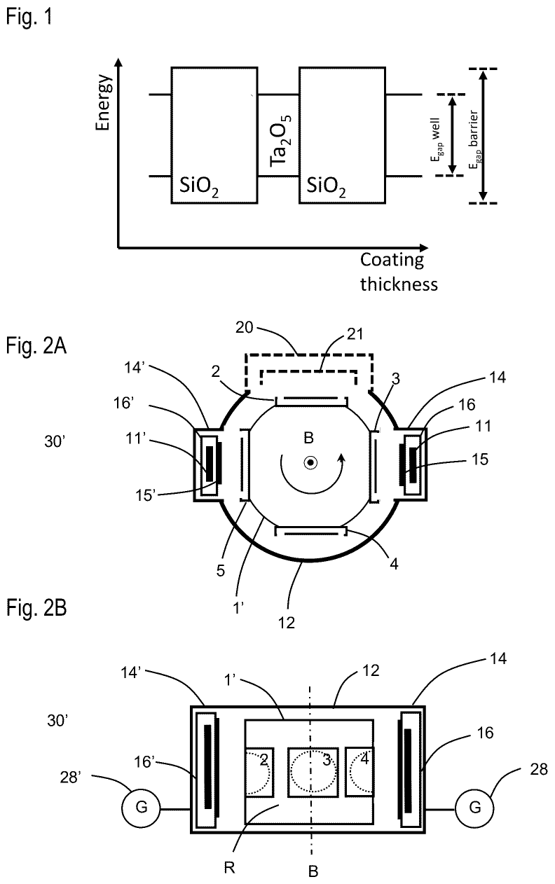

FIG. 1 shows an energy versus layer thickness scheme with a material combination SiO₂ for the barrier layer and Ta₂O₅ for the well layer in analogy to the general scheme with Steinecke as cited above. Even though optical coatings are typically amorphous and lack a well-defined band structure, an energy gap between quasi-free ground states and higher conduction states is present. This energy gap can be altered by limiting the structure size as, for example, the layer thickness in optical coating systems to very small values. Then the low index material will act as a barrier whereas the high index material acts as a quantum well. A periodic structure of high and low band gap areas will limit the electron mobility. The novel concept of so-called quantizing nanolaminates (QNLs) with a well layer thickness allows for independent adjustment of the optical band gap and the refractive index. The layer thickness of the quantum well, her the Ta₂O₅ layer needs to be below about 2 nm in order to see a significant change in the energy gap. The barrier thickness also needs to be in the same range, preferably thinner than the well to obtain a high effective refractive index.

FIG. 2A shows a top view whereas FIG. 2B shows a cross section through a simplified representation of a processing system 30′ comprising a cylindrical holder 1′ being rotatable round axis B. The processing system 30′ comprises also a sputter station 14, a further sputter station 14′, and an optional plasma station 20 (in dotted lines) with plasma source 21. Each sputter station 14, 14′ comprises a sputter source 16, 16′ with a respective planar elongated sputter target 15, 15′, also referred to as linear target, and is connected to a separate gas supply 28, 28′ to introduce sputter and/or reactive gas near the target. Wafers 10 are mounted to substrate supports 2, 3, 4, . . . along a height diameter of the cylindrical holder 1′. The targets are directed towards the cylindrical surface where the substrate holders are mounted which is the peripheral region R with this type of process system.

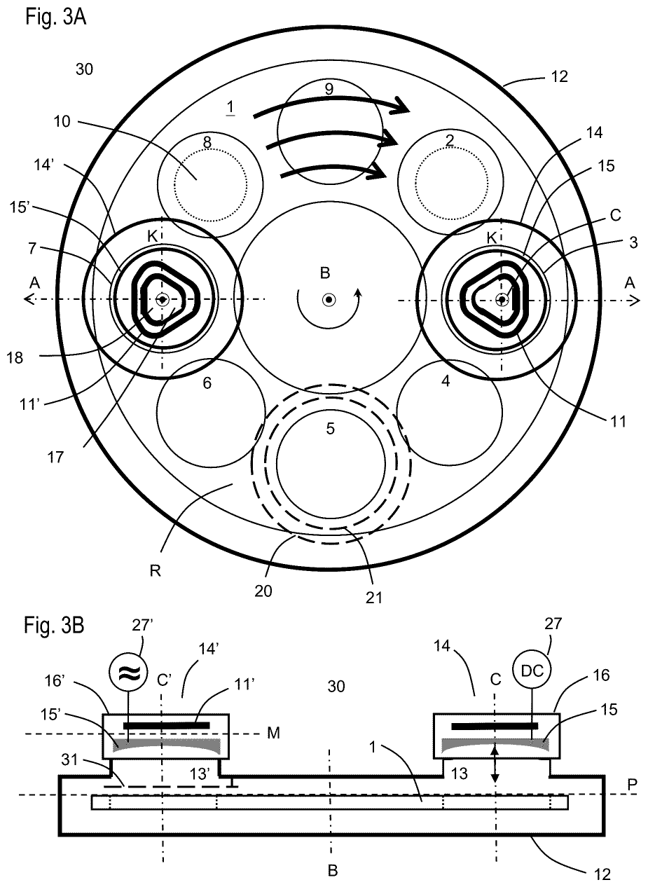

A further vacuum processing system is described with reference to FIG. 3A, which shows a top view, and FIG. 3B which describes a cross section through a simplified representation of a turntable processing system comprising a turntable holder. An enclosure or vacuum treatment recipient 12 has at least two, preferably three or more of sealable openings 13, 13′. They are provided to accept process stations here two sputter stations 14, 14′, comprising a sputter source 16, 16′ with a target 15, 15′, and an optional plasma station 20, with a plasma source 21. The targets can be moved along axis C, which is a Z-axis with reference to the substrate and turntable plane (see doble arrow in FIG. 3B) to define a substrate target distance according to the respective process needs. Inside the recipient 12 there is an essentially circular turntable holder 1 exhibiting locations for substrate supports 2-9 to hold substrates 10 (only shown with holder 2 and 8. The turntable's general surface also defines a plane P. The substrate supports 2-9 can be recesses matching the outer shape of the substrate to be treated, simple rims, pins, chucks, holders, clamps or mounts. In case substrates are being held by carriers, the mount could be a support for such a carrier.

Supports 2-9 are shown as of circular shape, this shall however not be a limiting factor for the shape of the substrate.

The turntable has a rotational axis B. A drive able to turn the turntable has been omitted in FIG. 3. An expert skilled in the art will choose an appropriate solution.

The number and shape of the substrate supports will be defined by geometrical constraints as well the specifications for the vacuum processing system.

Sputter sources 14, 14′ are shown arranged on opening 13 and 13′ and are connected to respective target supplies 27, 27′, which can be RF, DC, or pulsed DC, for each source the same type of supply or different supplies according to the process needs. PVD source 14 essentially comprises a circular material target 15 and a static magnet arrangement 11. The magnet arrangement defines a plane M which is parallel to plane P and, accordingly, perpendicular to axis B. A further axis C is the central axis through the circular target and is perpendicular to plane M and consequently parallel to axis B. This axis C also marks the centre of opening 13, 13′ respectively. The radial distance between axis B and C is chosen the same as between axis B and the centre of each substrate support 2 . . . 9. In other words, during each turn of the turntable the area of each of the substrates supports and openings 13, 13′ are fully aligned and completely face each other at least for the split of the second when the condition is met. The number of openings may match the number of substrate locations, but will be often smaller. To allow a ramp up of the targets without sputtering towards the turntable and substrates, an optional shutter 31 (in dotted lines) may be provided. Without shutter or with the shutter in an open position targets are directed to the upper surface of the turntable holder where the substrate holders are mounted which is the peripheral region R with this type of process system.

The PVD sources 16, 16′ exhibit static magnet systems 11, 11′ designed in a way to compensate the deposition inhomogeneity caused by the different tracks lengths of the rotational movement of a substrate passing by underneath. It is further designed in such a way to do without screens, shapers or shades.

The magnet system has a basic form as described in top view FIG. 3A, and includes two rings of magnets, one encircling the other and with opposite polarity. During operation the plasma tunnel essentially is trapped between the magnetic arches generated by those two magnet rings. The two magnet loops can basically exhibit the shape of a trapeze or a triangle with round corners but need not be symmetric as shown.

The magnet system 11, 11′ is shown with a line K and an axis A, which intersects and is normal to axis B but need not necessarily define two symmetric halves as shown. The line K intersects axis C and lies within plane M, it basically separates the area defined by the outer border of the magnetic system, the outer circumference of the outer coil in a plane defined by A/K in two halves of different size, namely a smaller inner magnet area 17 lying radially closer to the axis B and a larger outer magnet area 18 (reference numbers only shown with magnet system 11′), which extends away from the centre (indicated by the arrow at axis A). Such systems allow for homogeneous coating of the substrates and to compensate for systematic inhomogeneity induced by the substrate when passing with the turntable rotation on its curved arc-path as symbolized by the three arrows underneath a sputter source 16, 16′.

It has been shown that a coating homogeneity of less than 1% can be achieved on the equivalent substrate area of a 6″ wafer for a SiO₂ target, with a turntable process system comprising such magnetic systems. Further details about such magnetic systems can be found in WO 2017/042123 A1 of the same applicant.

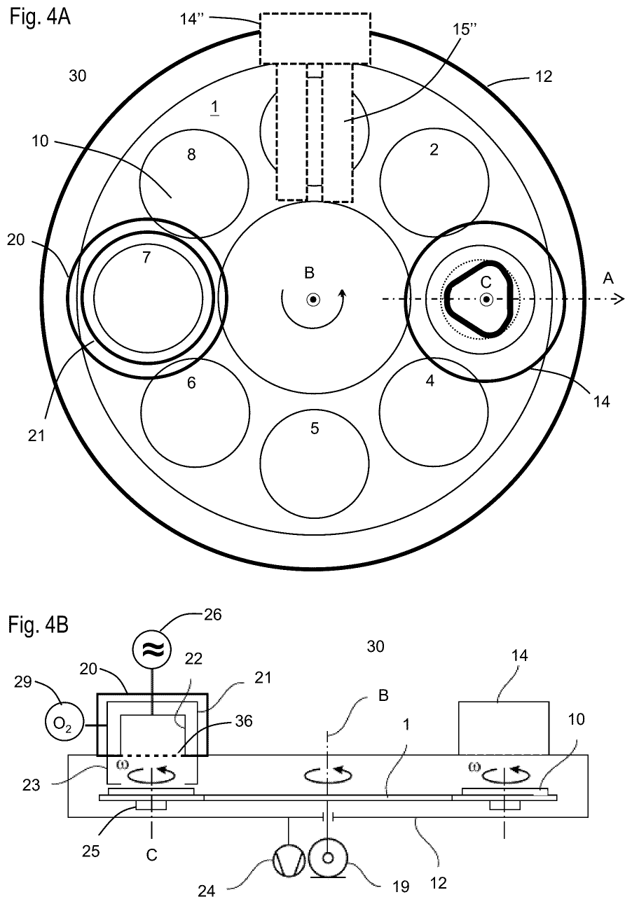

A similar turntable process system as shown with FIG. 3A, 3B is described with reference to FIG. 4A, again in top view, and FIG. 4B, as a cross section. This is a basic system 30 for the deposition of a-Si layers with one sputter station 14, and to oxidize the layer in the following with the plasma source 21 of the plasma station 20, which here is shown simplified in one. Any target features as shown with the forgoing FIG. 3 can be the same but left away for better clarity. An oxygen supply is connected to the plasma station and the cup like first electrode 22 having a larger electrode surface is connected to a plasma power supply, which is an RF-source 24, to ignite and maintain the treatment plasma. A grid 36 is mounted in the plasma outlet as a part of a second ground electrode having a smaller electrode surface (not shown in detail). A pumping arrangement 24 for the evacuation of the process system 30 and a turntable drive are here explicitly shown. Separate pumping of the plasma station 20 and/or the target station 14 is optional (not shown). In addition, in FIG. 4B also separate substrate drives 25 are shown, which are integrated into the turntable. These drives rotate the substrates round axis C to optimize layer distribution and treatment during the different treatment processes in the stations 14, 20. Features as mentioned with FIG. 4A,B can also be applied to other process systems, especially to turntable systems as shown with FIG. 3A, B. A confinement shield 23 operated on ground potential being a part of the smaller (ground) electrode reaches near above the surface of the substrates and/or the turntable and confines the plasma coming out of the grid 36 of the smaller electrode. Thereby a good and sufficient separation of the plasma station can be provided to prevent process disturbances in the sputter station(s).

An optional additional dual magnetron sputter source 14″ comprising two rotary targets 15″ is shown in dashed lines in FIG. 4A. Such sputter sources, where targets are operated alternatingly as cathode and anode and thereby avoid any target poisoning effectively, can be used in addition or instead of target stations 14, 14′ with disc-like targets 15, 15′ as shown before with FIG. 3B. In the same way a sputter station with two linear targets driven in a dual magnetron configuration, or more simply sputter stations with one linear planar or rotary sputter cathode, respectively target can be used up to the respective process needs.

### Experimental Set Up

For the QNL deposition and layer deposition for the optical devices as discussed below, an Evatec Clusterline BPM magnetron sputter deposition system has been used, which is a commercially available process system, respectively a vacuum recipient with a turntable, a plasma station, and up to four magnetron sputter sources in sputter down configuration, as discussed above with FIG. 3A,B and

FIG. 4A, B. The plasma source can be used in standard deposition to influence layer properties such as stress or surface roughness. For the deposition of Ta₂O₅—SiO₂ QNL the use of the plasma source enables to run the two sputter sources in a very wide parameter range. In the deposition of a-Si and SiO₂ however, the plasma source has been used to oxidize the top part of the a-Si layer deposited under the Si-sputter source. Therewith a respective process system with two sputter stations and a (further) plasma station is a very versatile process system which refers especially to recipients with turntable holders but can also be transferred to recipients with a cylinder or cylinder-like multifaceted holder. All stations can be provided with POM-systems.

This deposition system has a capacity of 15 substrates of diameter 200 mm. Substrate loading is executed automatically through a load-lock. Oxides are deposited reactively in pulsed DC mode and use Plasma Emission Monitoring PEM to work in the transition mode close to or even within the hysteresis loop and thereby assure full oxidation at a high deposition rate. It is also equipped with broad band and monochromatic optical monitoring.

The turntable configuration is perfectly suited for the deposition of QNL. With the continuous table rotation substrates pass repeatedly beneath the active sputter sources with shutters open, if shutters should be used. Therewith the substrates are exposed to both sources with each rotation. By setting the sputter power of the two sources to respective different values the ratio of the thickness of the two materials can be defined and varied, and therewith can be varied the index of refraction of the stacked QNL-film, i.e. the stack of nanolayers (sum of Lₕ and sum of Lₗ) which is a so called metamaterial combining the features of the two materials in a new way, see also below. The thickness of the individual layer pairs in the QNL-film can be further determined by the rotation speed of the table, but not the material ratio. Further deposition parameters, which influence the growth rate and material properties are the gas flows of argon and oxygen and the PEM set-point, e.g., intensity and spectral line chosen from the gas-plasma respectively from the target plasma emission.

In the case of a material combination of amorphous silicon and SiO₂, the QNL structure is obtained in a slightly different way. In this case the Si-source is used to deposit the amorphous silicon in a pure Ar-plasma and the oxidation is performed when passing beneath the plasma source which in this case is always operated with oxygen. Again, table speed and process settings of the sputter and plasma sources define the thickness of the two nanolaminate materials.

The samples were deposited on double side polished Herasil-glass samples. These were characterized by spectrophotometry in transmission and reflection both at an angle of 8° on the exact same spot on the sample by using a PhotonRT spectrometer by EssentOptics.

The effective refractive index n and the extinction coefficient k in the transparent range of the coating were determined using OptiChar by Optilayer. The models used were normal dispersion for n and UV-Vis mode for k. This evaluation also allows to determine the physical thickness d or dₜₒₜ of the metamaterial.

The effective refractive index of the resulting metamaterial is defined by the ratio of high and low refracting materials and can be calculated by applying the effective medium theory, where f is the volume ratio between high and low refracting materials according to A. Feldman, “Modeling refractive index in mixed component systems,” in Modeling of Optical Thin Films (1988), Vol. 0821:

$${n}_{eff}^{2} ( λ ) = f {n}_{high}^{2} ( λ ) + ( 1 - f ) {n}_{low}^{2} ( λ ) \qquad ( 1 )$$

The effective refractive index N_{eff} is derived from the spectral measurements in T and R as detailed above. The refractive indices of n_{high} and n_{low} are derived from Ta₂O₅ and SiO₂ single layers. The values used were: Ta₂O₅ n_{high}=2.168 and SiO₂ n_{low}=1.474, both indices relate to a wavelength of 500 nm. Formula (1) then allows to calculate the volume ratio f of the two materials.

The thickness per table pass can be calculated by dividing the physical thickness d of the metamaterial by the table speed given in seconds per pass. The thickness of the individual layers for Ta₂O₅ and SiO₂ can be calculated by multiplying the total thickness per pass by the factor f respectively (1−f).

The optical band gap was determined using the Tauc-plot method as explained with B. D. Viezbicke, S. Patel, B. E. Davis, and D. P. Birnie, “Evaluation of the tauc method for optical absorption edge determination: Zno thin films as a model system,” Phys. Status Solidi B 252, 1700-1710 (2015).

Results for Ta₂O₅/SiO₂-QNLs

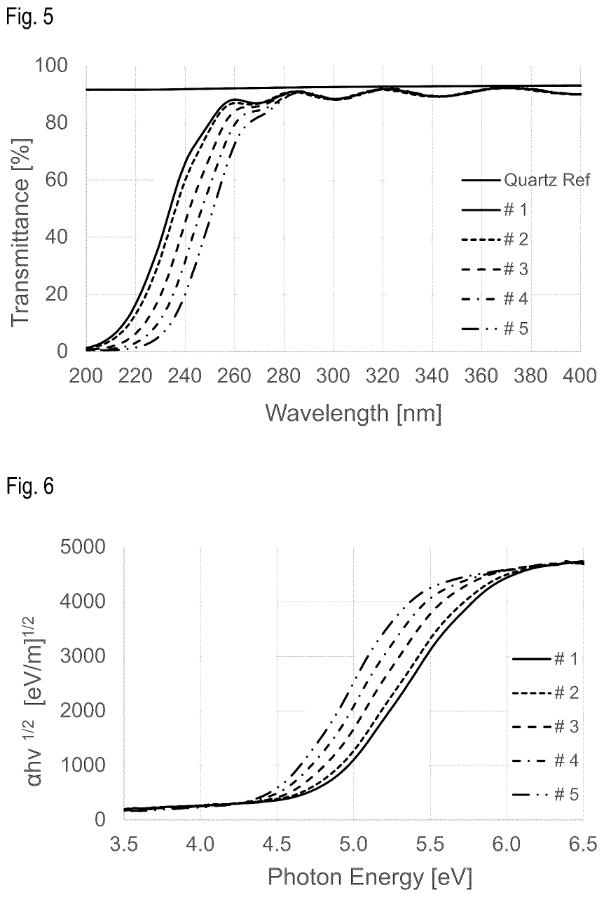

In a first experiment the Si and Ta sources were run at 6 and 5 kW each. The table speed was varied from 3 to 15 seconds per pass, which means that the ratio of high to low layers stayed constant, but the individual layer thickness increased the slower the table turns i.e., the longer the time per rotation pass is. According to the theory it was expected that the absorption edge would shift towards shorter wavelength the thinner the individual well layers were, whereas the effective refractive index would remain constant for all four samples. With FIG. 5 the transmittance curves for following experiments are shown below the reference curve of the quartz glass (Herasil):

| | | | |
|---|---|---|---|
| #1: | 3 s/pas | #4: | 12 s/pas |
| #2: | 6 s/pas | #5: | 15 s/pas |
| #3: | 9 s/pas | | |

As can be seen with FIG. 5 the predicted trend can be observed indeed, the absorption edge of sample #1 lies at the shortest wavelength, whereas sample #5 lies in the longest absorption edge, the difference at T50% is about 19 nm. In the longer wavelength range away from the absorption edge all curves overlay since they all have the same effective refractive index. From these measurements it can be concluded that the magnetron sputtered nanolaminates do show the quantization effect.

FIG. 6 shows the Tauc plot for the same experiments, which plots the values αhν^{1/2} [eV/m]^{1/2} versus the photon energy. The gap energy is obtained by linearly extrapolating the transition region to αhν=0, where the intersection to the photon energy axis equals the gap energy, which is proportional to the difference of the energy gaps, ΔE_{gap}=E_{gap_THINN}−E_{gap_THICK}=E_{gap_high}−E_{gap_low} as shown in FIG. 1. As can be seen here, #1 the experiment with the thinnest well layer Lₕ is shifted towards the highest photon energy, while the experiment with the thickest well layer #5 shows the least shift.

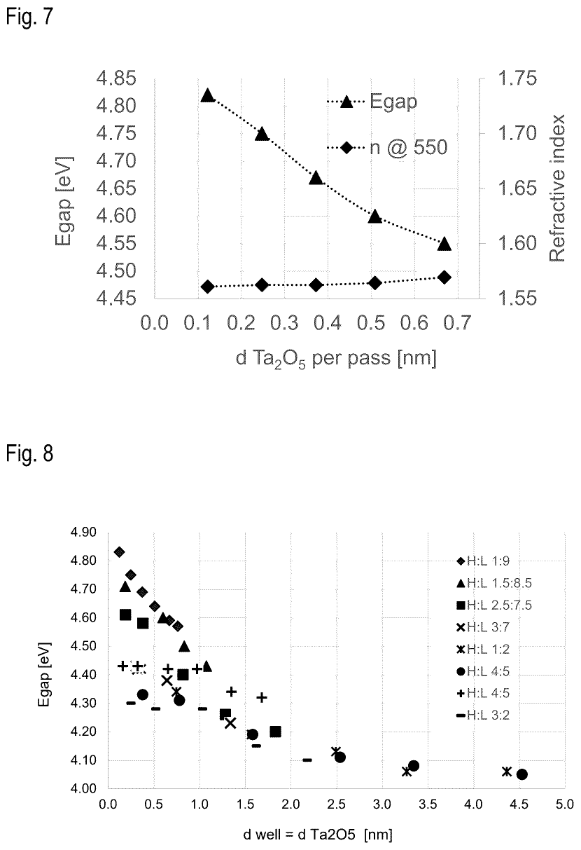

For the same set of samples, the effective refractive index and the energy gap were then determined and calculated as described with the experimental set up. The curves as shown in FIG. 7 (refractive index: right scale, tilted squares; energy gap: left scale, triangles) show that the gap energy increases, with the decrease of well thickness, which is the thickness d of Ta₂O₅. However, the refractive index remains constant at a value of about 1.56, which corresponds to a thickness ratio of 1:9 for Ta₂O₅ and SiO₂. Both findings are in perfect agreement with the conclusions, which were already drawn from the transmission measurements. The shift in the absorption edge proves that these stacks consists of nanolaminates and are not simply a mixture of both materials.

The total physical thickness of the respective layer stacks in FIG. 5-7 is in the range of 700-704 nm, which translates to 600 pairs of nanolaminate layers at a table speed of 3 s/pass.

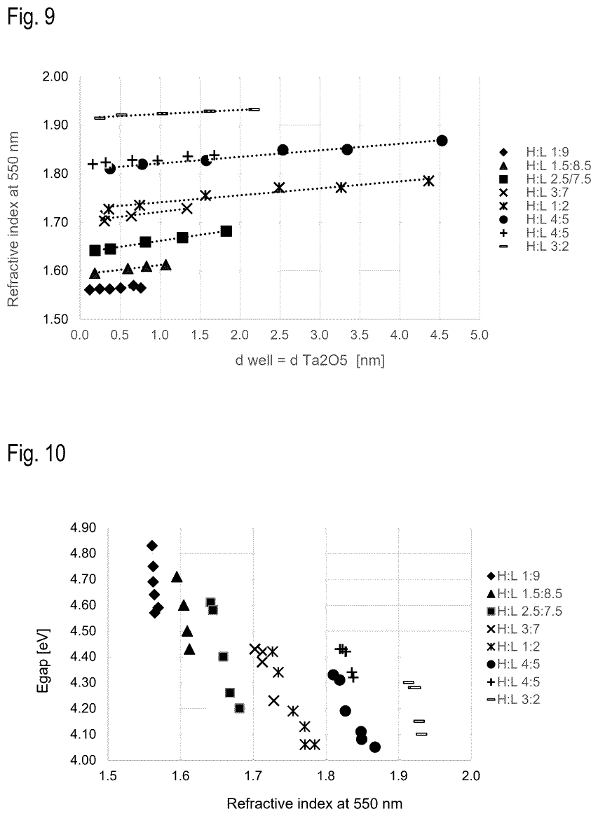

Subsequently, a series of experiments were performed varying the ratio of the thicknesses of Ta₂O₅ to SiO₂. As a main parameter the target power on each target was varied. Since both sputter processes are PEM-controlled, the PEM settings also had to be adjusted to the values appropriate to the sputter power. For each H: L ratio a set of runs with different table speeds was deposited in order to vary the thickness of the individual nanolaminate layer. Typically, table speeds of 1.5/3/4.5/6/9/12/15 s/pass were chosen. On the right side of FIG. 8, as with FIGS. 9 and 10 which refer to the same test series, the ratio (d_{h_tot}/d_{l_tot}) of the high index material (d_{h_tot}=n*dₕ) to the low index material (here d_{l_tot}=n*dₗ) is displayed for each test series. Thereby FIG. 8 again shows that, the energy of the gap increases the thinner the well thickness is. For Ta₂O₅ with well thickness exceeding 2-3 nm however the gap energy becomes approximately constant because thicker layers do not show quantization effects.

The refractive index on the other hand, as shown in FIG. 9 against the well thickness and in FIG. 10 with the energy gap, only shows a slight, but steady increase, with increasing well thickness, the effect being more pronounced the higher the refractive index is. As can be seen from FIGS. 9 and 10 the refractive index can be tuned in a very wide range and can basically span the entire range of indices from SiO₃ to Ta₂O₅.

Use of QNL with Optical Devices for Ta₂O₅/SiO₂-QNLs

The above results demonstrated that magnetron sputter deposition is capable of manufacturing nanolaminates showing the quantum effect. In the following it is demonstrated that optical interference coatings such as antireflection (AR) coatings, mirrors or filters can be designed and manufactured by replacing the high refractive material by a QNL stack of the appropriate total thickness.

As an example, to show the viability of the QNL concept for optical interference coatings, an antireflection coating for a UV LED centered at 280 nm was chosen. The design is based on a 2-layer design. For the experiment a QNL-film with an effective refractive index of n=1.7 at a wavelength of 550 nm and a E_{gap}=4.48 eV was designed. Such a nanolaminate stack consists of Ta₂O₅ and SiO₂ layers with a thickness of 0.31 and 0.76 nm respectively. The design uses a physical thickness of 120 nm for the total thickness of the QNL i.e., about 120 individual nanolayers (120/1.07=112.14 layers) of each material and a physical thickness of 136 nm for SiO₂. The total thicknesses correspond to an optical thickness of about 3 times λ/4 at λ=280 nm.

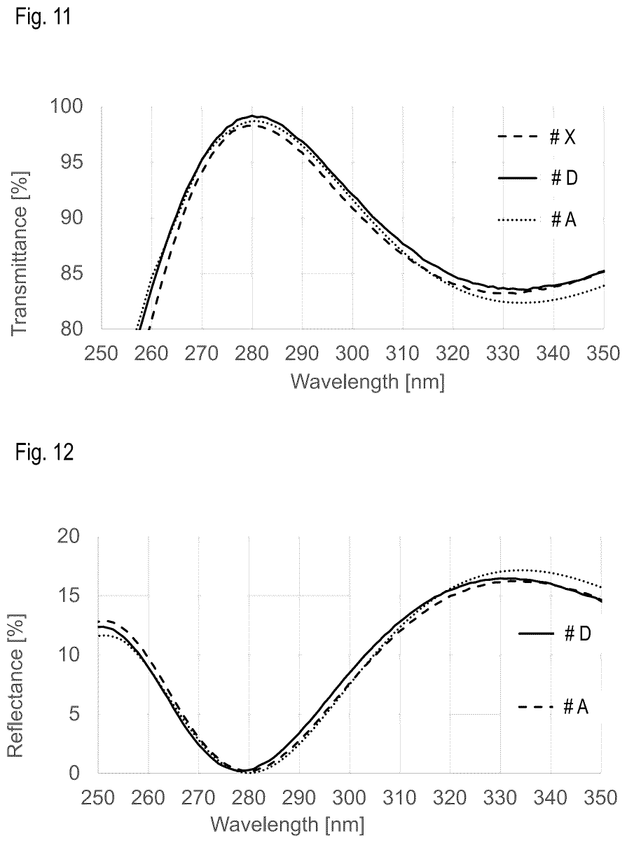

FIGS. 11 and 12 show the transmission respectively the reflection curves of a double side coated quartz substrate, which can be used as an AR-device. Minimum reflection and maximum transmission occur at the design wavelength of 280 nm and the curves of the device with the coating as deposited (#D) and as annealed in a further processing step (#A) correspond nicely with the design curve (#X). The transmission of the double side coated sample reaches 98.3% as deposited and 99.2% after annealing for 1 hour at 300° C. in air. The corresponding absorption losses are 1 and 0.3%. As a comparison, a 2-layer antireflection coating composed of Ta₂O₅ (d=100 nm) and SiO₂ optimized for a transmittance at 266 nm resulted in minimum reflectance at the design wavelength but 66% and 25% absorption at 266 and 280 nm respectively. This clearly shows that a “bulk” Ta₂O₅ layer cannot be used at these UV-wavelengths, whereas with a QNL consisting of a Ta₂O₅/SiO₂-QNL, a very good performance can be obtained, opening the field for a wide range of further applications. In conclusion, a QNL film can be treated in design and optical monitoring as regular “bulk” layers with the corresponding effective refractive index. Since two sputter sources are running the deposition rate with typically 0.71 nm/s for the AR QNL is higher than for the corresponding single layers of SiO₂ or Ta₂O₅.

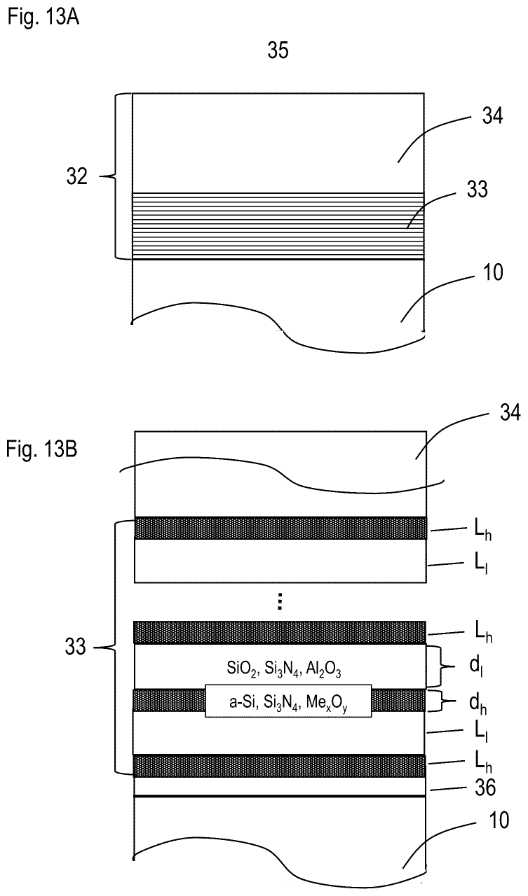

FIG. 13A shows a scheme of one side of an inventive optical device 35, here an AR-device, which can be coated in a simple embodiment as a two film 33, 34 system on one side of the substrate 10 only, as shown, or on both sides as described above. The QNL-film 33 here represents the high index material of the AR-coating, which can be designed for a specific desired index of refraction as shown above, whereas the low index film 34 is chosen from a known low index “bulk” material, e.g., SiO₂. For ease of production the low index “bulk” material and the low index material of the QNL-film can be the same.

FIG. 13B shows the same device with a magnification of the QNL-film 33 with layers Lₕ of high refractive index material of thickness dₕ, and layers Lₗ of low refractive index material of thickness dₗ. Materials which can be used for the high index layers Ln are amorphous silicon (a-Si), silicon nitride (e.g., Si₃N₄) and MeₓO_{y}, where Me=Al, Ti, Zr, Hf, Nb, Ta, or Ge. Materials which can be used for the low index layers Li are silicon oxide (e.g., SiO₂), silicon nitride (e.g., Si₃N₄), and aluminum oxide (e.g., Al₂O₃). An expert of the art knows that whenever silicon nitride or aluminum oxide is used as the high index layer material, the low index layer material will be silicon oxide due to its respective lower index of refraction. The QNL-film 33 of the metamaterial can be deposited directly or via an optional adhesion layer 36 to the substrate. Alternatively, the first layer of the low index material of the QNL-stack could be used as adhesion layer 36 which then will have the same layer thickness dₗ as layers Lₗ. With both FIG. 13A, B curved lines stand for an incomplete presentation of the substrate 10 due to the very different dimensions of the substrate and the film, respectively in FIG. 13B for an incomplete presentation of the low index film 34 due to the different dimensions of the nanolayers Lₕ, Lₗ and the low index film 34.

In-situ broadband optical monitoring in reflection in a wavelength range of 380-980 nm was investigated. Thanks to the thicker layers the signal could be observed over longer time evolving also through reflection maxima. It turned out, that the reflection signal of the QNL developed completely regular, exactly as a layer with the corresponding effective refractive index would evolve and is therefore perfectly suited for controlling the thickness in film stacks with QNLs.

As a second example of the QNL concept for optical interference coatings a mirror for 355 nm was deposited consisting of 30 layers each of SiO₂ and QNL Ta₂O₅—SiO₂ with quarter wave optical thickness. As a comparison, the equivalent mirror with a standard design was deposited with 26 layers total of SiO₂ and Ta₂O₅ of quarter wave optical thickness.

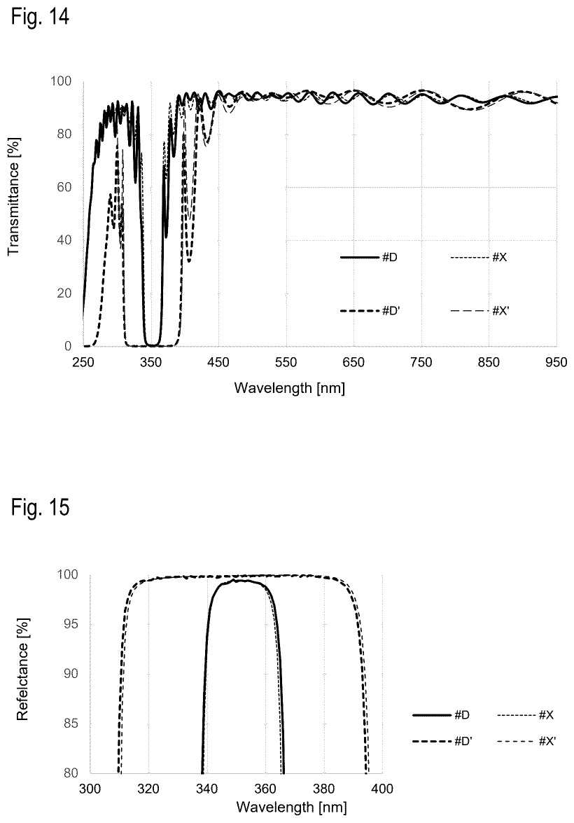

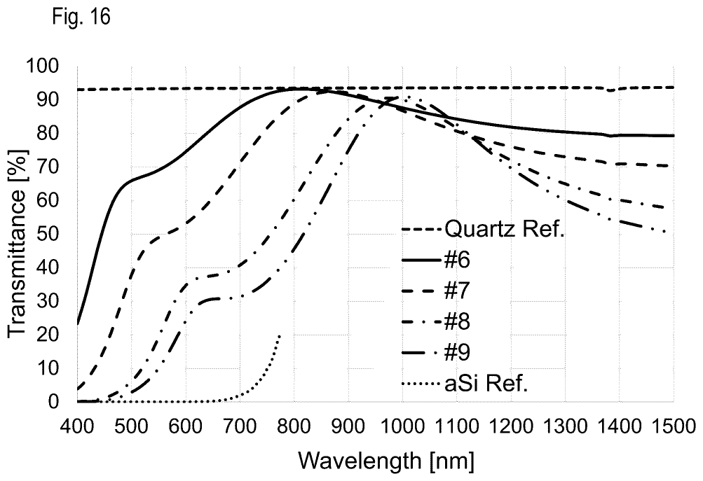

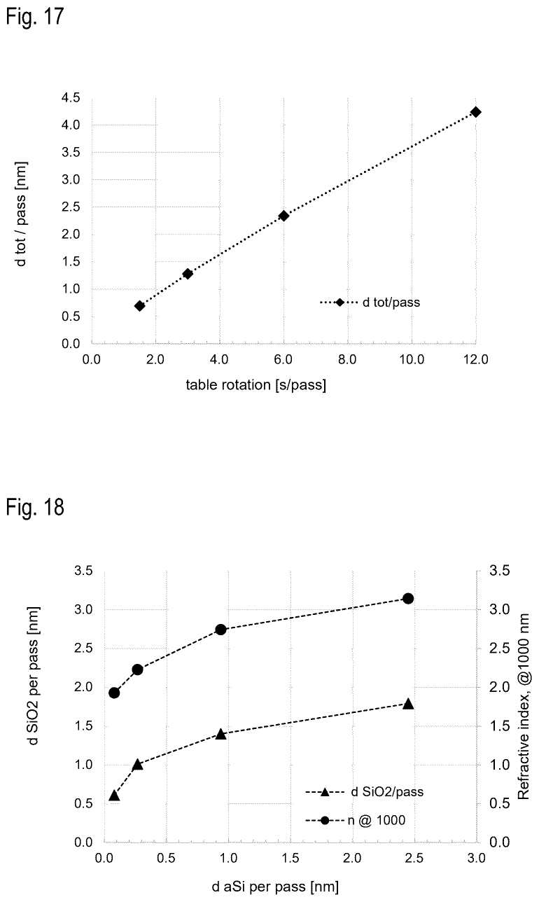

Both designs were deposited using broadband optical monitoring. The good agreement between measurement and design indicates, that the QNL-layers could be applied as if they were regular layers, see transmittance and reflectance spectra of the respective coatings in FIG. 14 and FIG. 15. The curves of the device with the QLN-coating as deposited respectively as calculated are referred to as #D respectively #X. The curves of the comparative coating #D′ and #X′. Both mirrors are centered nicely at the design wavelength. As expected, the mirror with QNLs has a narrower reflection band due to the lower effective refractive index of the QNL. When comparing the transmission region below the wavelength of 300 nm it becomes obvious, that the standard design only shows poor transmission, whereas the QNL-mirror only has losses in the range of 2-5% above the absorption edge.

Results for a-Si/SiO₂ QNLs

The samples again were deposited on double side polished Herasil-glass samples, which is a fused silica glass, also named quartz glass or silica glass, which has been fused from grown quartz crystals. These glasses are high-quality optical glasses that are free of voids and inclusions and exhibit optical homogeneity at least in the functional direction. All a-Si/SiO₂ samples were annealed in air for one hour at 280° or 500° C.

In a first experiment, the Si sputter source and plasma source were run at 5 and 1 kW respectively. When the sample passes the sputter source a film of amorphous silicon is deposited. With the table rotation this sample is then translated to pass beneath the plasma source where a part of the previously deposited a-Si layer gets oxidized. This sequence is repeated for a defined coating time.

In a first experiment, the table speed was varied from 1.5 to 12 seconds per pass resulting in an increasing thickness of the individual nanolaminate layers. The coating time was fixed for this series of four samples and resulted in a nanolaminate stack thickness of approximately 180 nm. In Fehler! Verweisquelle konnte nicht gefunden werden. the curves of the in spectrophotometric measurements transmission of the 4 runs reveals three characteristics of the layers: the wavelength of the absorption edge, the losses in the transparent wavelength range and the refractive index of the layers. The transmittance curves for following experiments are shown below the reference curve of the quartz glass (Herasil):

| | | | |
|---|---|---|---|
| #6: | 1.5 s/pas | #8: | 6 s/pas |
| #7: | 3 s/pas | #9: | 12 s/pas |

First, the absorption edge of this series of deposition runs shifts towards shorter wavelength the faster the table speed is set. The absorption edge of the sample with 1.5 s/pass lies at the shortest wavelength, whereas 12 s/pass results in the longest wavelength with a difference of about 280 nm between the samples for a fixed transmission of 80%. For comparison, the black dashed line indicates the onset of transmission of a regular amorphous silicon layer.

Secondly, the transmission maxima at half wave optical thickness (λ/2) closely touch the solid line of the uncoated quartz indicating low absorption of the QNLs in the longer wavelength range.

Thirdly, the transmission at 1500 nm increases with table speed. This is indicative of a reduction in effective refractive index of the nanolaminates. In the following we will first explain the shift in refractive index and then the shift in the absorption edge.

As explained in the experimental section the effective refractive index n_{eff} and the total layer thickness dₜₒₜ can be determined from the transmission and reflection measurements. The thickness deposited per table turn can then be obtained by dividing dₜₒₜ by the number of table-turns. As expected, the thickness deposited per turn is linear with the table speed, as can be seen in Fehler! Verweisquelle konnte nicht gefunden werden. However, the individual thicknesses of a-Si to SiO₂, calculated as described in the experimental section, do not increase linearly as can be seen from Fehler! Verweisquelle konnte nicht gefunden werden. In the run with the fastest table speed an a-Si layer of 0.7 nm thickness was deposited, which was subsequently oxidized by the oxygen plasma of the PSC to an SiO₂ layer with a thickness of 0.6 nm. For the slowest table speed of 12 s/pass however the 4.2 nm a-Si only gets oxidized to a thickness 1.8 nm SiO₂. The decrease in oxidation rate is expected, however, since the energetic oxygen species generated in the plasma source have a limited penetration depth even if the exposure time is extended. In consequence thicker layers have a reduced fraction of SiO₂, which in turn will lead to a higher refractive index. Indeed, this increase in refractive index is confirmed as can also be seen in Fehler! Verweisquelle konnte nicht gefunden werden. on the right axis.

In a next step the shift of the absorption edge is investigated in more detail. The strong shift in absorption edge as seen in Fehler! Verweisquelle konnte nicht gefunden werden. can mainly be attributed to the change of the average stoichiometry over the total thickness of the nanolaminate stack. In order to see whether a quantum effect is present, nanolaminate films with increasing thicknesses of a-Si and SiO₂, but constant thickness ratio have to be compared. For this to be the case, adjustments had to be made in the process settings such as Si source power and oxygen flow.

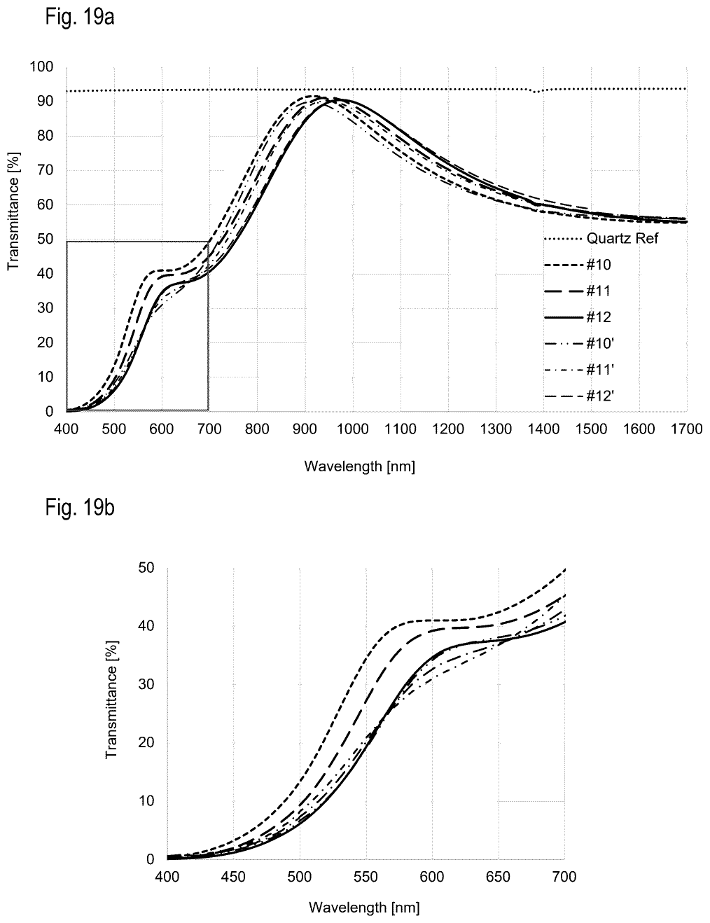

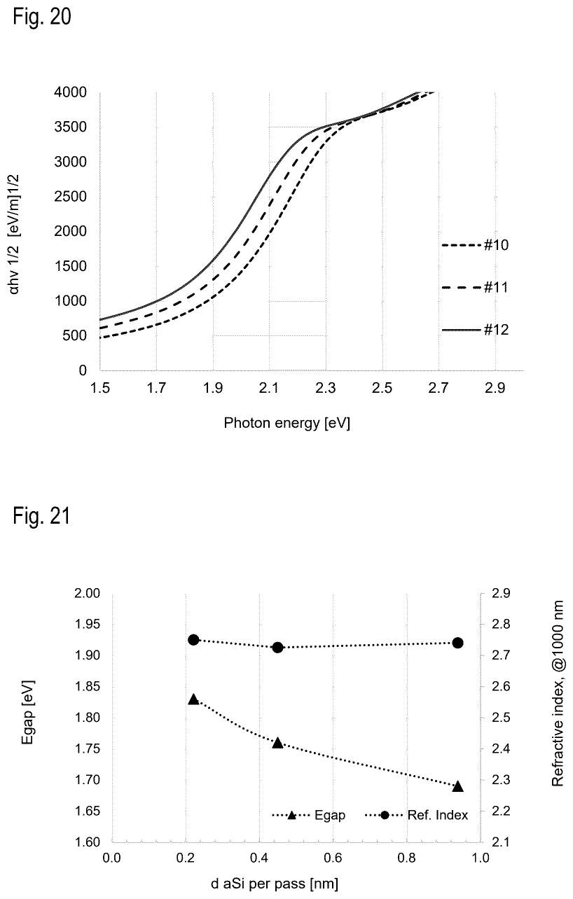

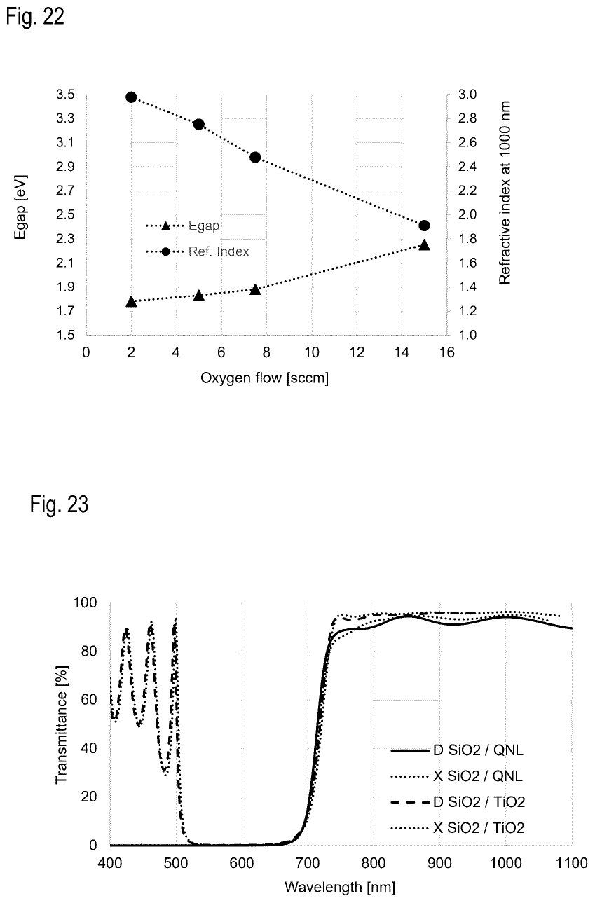

An example of such an experiment is shown in Fehler! Verweisquelle konnte nicht gefunden werden. (a): runs 10-12 have a constant ratio of SiO₂:a-Si, and thus the same average composition, but increasing total thickness per pass of #10=0.5, #11=1.1, and #12=2.3 nm. The transmission measurement of the three runs shows a shift in absorption edge. It is shown now that the films as deposited show a quantization effect. In a first step the refractive index and extinction coefficient of run #12 (continuous line) were determined. The dash-dotted lines denominated #10′, 11′ and 12′ in FIG. 19a) and b) show the simulation of the transmission curves based on this dispersion data considering the slightly different layer thicknesses of runs 10 to 12. As expected for a mixture the three simulated curves overlay in the absorption region below 600 nm. This is in discrepancy to the measured curves of the deposited coatings #10, #11, #12, which show an edge shift to shorter wavelength the thinner the well material a-Si is. The final confirmation of quantization is seen in the shift of the band gap energy in Fehler! Verweisquelle konnte nicht gefunden werden., which was determined from the Tauc-plot as described above. Fehler! Verweisquelle konnte nicht gefunden werden. shows the increase of the gap energy when decreasing the a-Si well thickness, while the refractive index remains constant within measurement accuracy. A shift of 0.15 eV is observed, which corresponds to a shift of 60 nm in wavelength. This observation confirms that the quantization effect can be observed also in the material system a-Si/Sio-deposited by magnetron sputtering.

Subsequently, experiments were performed varying different deposition parameters. Fehler! Verweisquelle konnte nicht gefunden werden. shows the dependance of the gap energy and the refractive index with oxygen flow in the plasma source for a series of runs with table speed of 1.5 s/pass. With an increasing availability of oxygen in the plasma, the SiO₂ nanolayer thickness increases and thus the refractive index decreases while the gap energy in turn increases.

Use of QNL with Optical Devices for a-Si/SiO₂ QNLs

### Longpass Filter

As shown in the previous section QNLs in the system a-Si/SiO₂ can be manufactured within a wide range of refractive indices and gap energies. The nanolaminate of run #10 from the previous section was chosen as the high and SiO₂ as low refractive index material to deposit a long pass filter. As described in the experimental section, the QNL was deposited using the Si sputter source in combination with the plasma source, whereas the SiO₂ layers were deposited from the additional sputter source. A design with 16 layers of ¼ optical thickness has been chosen with some of the outer layers being adjusted to provide an edge formed curve. Material #10 has a refractive index of 3.18 and 2.79 at 550 and 1000 nm respectively and an E_{gap} of 1.72 eV. In this case a high index layer with optical thickness of ¼ has a physical thickness of 49 nm and consists of a total of 180 alternating layers of a-Si and SiO₂. Thanks to the turn table configuration of the BPM magnetron sputter deposition system, the deposition rate of the nanolaminate is as high as for a standard a-Si layer.

In-situ broadband optical monitoring in reflection in a wavelength range of 380-980 nm has been used to monitor the coating thickness. It turned out, that the reflection signal of the QNL developed completely regular, exactly as a layer with the corresponding effective refractive index would evolve. It can therefore be concluded that optical monitoring is perfectly suited for controlling the thickness in film stacks with QNLs.

For comparison, the same type of filter has been deposited based on the standard material combination SiO₂—TiO₂ also using 16 layers, based on the same design principle as the nanolaminate filter. In Fehler! Verweisquelle konnte nicht gefunden werden. the curves of the device with the QLN-coating as deposited respectively as calculated are referred to as #D_{SiO2/QNL} respectively #X_{SiO2/QNL}, where QNL refers to a respective a-Si/SiO2 stack. The curves of the comparative coating as deposited respectively as calculated are referred to #D′_{SiO2/TiO2}, respectively #X′_{SiO2/TiO2}.

it becomes immediately apparent that the standard design does only block half of the visible range, whereas the QNL design blocks the entire range. Of course, it is possible to reach full blocking with an SiO₂—TiO₂ design, however at the expense of double the number of layers.

The standard SiO₂—TiO₂ coating has a total thickness of 1.4 μm as compared to 1 μm for the QNL-SiO₂ design. Furthermore, the deposition rate of the QNL is about double the rate of TiO₂. Both reduced thickness and increased deposition rate result in a cut of the deposition time by a factor of 2. Thus, this comparison shows the large potential of the new nanolaminate material to significantly boost productivity and reduce manufacturing cost.

As demonstrated above magnetron sputtering using a deposition tool with turntable configuration is ideally suited for the deposition of quantum nanolaminate layers and coatings. The individual layers of the nanolaminate stack are deposited sequentially, the amorphous silicon is deposited when the substrate passes under the silicon source and the SiO₂ is produced by oxidation of the top part of the a-Si layer when passing the plasma source. This sequence is repeated with every rotation of the turntable. The setting of the table rotation speed allows to select the total thickness of a-Si and SiO₂ per turn, whereas the power setting of the sputter and plasma sources allows to set the thickness ratio of a-Si and SiO₂. We demonstrated individual layers with a few tenth of nm and a wide range of a-Si volumetric fractions f=V_{a-Si}/V_{SiO2} of 0.1-0.75.

The single layers show a large shift in the absorption edge. The analysis of the data revealed two mechanisms causing the shift. First, a change in composition leads to a shift of the absorption edge to shorter wavelength the higher the SiO₂ fraction in the film is. This is an effect, which is well known. The second effect, however, caused by quantization, is demonstrated for the first time in a-Si/SiO₂ layers to the best of the inventors knowledge. QNL with the same average composition show a shift in absorption edge when the thickness of the a-Si barrier layer decreases. This is in accordance with theory, as described in the theory section 2.

In a next step, QNL layers were used as the high index material in an optical interference filter. It has been demonstrated that the turntable configuration of the sputter system leads to a viable manufacturing process for a long pass filter blocking the visible part of the spectrum while transmitting the NIR. From a t technical standpoint the deposition of these filters runs like a standard process with the difference that in the QNL layer two sources are powered. Furthermore, optical monitoring can also be used without any adaption.

The long pass filter coating was in good agreement with the design and showed good transmission in the wavelength range above 700 nm, thus confirming the precise and reproducible deposition in the sub-nm range. As a comparison a standard SiO₂/TiO₂ long pass filter was also deposited. This showed that with the same number of layers the blocking range was much narrower than for the QNL design. For a standard filter with the same characteristic as the QNL filter double the number of layers would be required. This clearly shows that the concept of QNL indeed opens up a wide field for novel applications with significant improvements in productivity.

### REFERENCE SIGNS LIST

1, 1′ rotatable holder (turntable and cylindrical)
2-9 substrate supports
10 substrate
11, 11′ (further) magnet system
12 recipient
13, 13′ opening
14,14′,14″ (further) sputter station
15,15′, 15″ (further) target
16, 16′ (further) sputter source
17 inner magnet area
18 outer magnet area
19 turntable drive
20 plasma station
21 plasma source
22 plasma generating electrode
23 confinement shield
24 pumping arrangement
25 substrate drive
26 plasma power supply
27 target supply
28, 28′ gas supply from sputter source
29 gas supply from plasma source
30, 30′ process system
31 target shutter
32 AR-coating
33 QNL-film
34 film of low refractive index material
35 optical device
36 grid (ground electrode)
37 dual magnetron
38 rotary cathode
A axis
B rotational axis
C axis (optional rotational)
K line
Lₕ, Lₗ Nanolayer(s) of high and low index material
dₕ, dₗ thickness of Lₕ, Lₗ

1. A process to deposit nanolaminates on a surface of a flat substrate, the process comprising:
mounting the flat substrate in a recipient on a substrate support in a peripheral region of holder having a central axis, the recipient comprising at least one magnetron sputter station having a sputter source and a sputtering target mounted to the sputter source and at least one plasma treatment station having a plasma source, wherein the sputtering target and the plasma source are directed to different sections of the peripheral region,
pumping down the recipient,
rotating the holder at a rotation speed round a central axis,
introducing a sputtering gas into the recipient,
introducing a reactive gas directly into at least one of the sputter station and the plasma station,
igniting a magnetron discharge in the sputter station and setting a magnetron power level (Pₘ) of the magnetron sputter station,
igniting a plasma in the at least one plasma treatment station and setting a plasma power level (Pₚ) of the plasma source,
exposing the flat substrate by the rotation of the holder
to the magnetron discharge to deposit a well layer Lₕ of high refractive index material having a layer thickness dₕ, and
to the treatment plasma to produce a layer Lₗ of low refractive index material,
wherein the layer thickness dₕ is:
0.1≤dₕ≤6 nm.

2.-24. (canceled)

25. An optical device comprising a substrate and an optical coating deposited on at least one side of the substrate, the optical coating comprising at least one film of high refractive material and at least one film of low refractive material, wherein at least one of the films is a quantized nanolaminate (QNL) film of a defined high or low overall QNL-index of refraction (n_{QNL}), whereas the QNL-film comprises at least one well layer Lₕ of high refractive index material having a layer thickness dₕ and at least one barrier layer Lₗ of low refractive index material, wherein the layer thickness dₕ is:
$$0.1 \leq {d}_{h} \leq 6 nm .$$

26.-32. (canceled)

33. A vacuum process system to deposit quantized nanolaminates (QNLs) comprising at least one well layer Lₕ of high refractive index material and at least one barrier layer Lₗ of low refractive index material, on a surface of a flat substrate, comprising:
a recipient,
a holder having a central axis and a substrate support in a peripheral region of the holder,
at least one magnetron sputter station having a sputter source and a sputtering target mounted to the sputter source,
at least one plasma treatment station having a plasma source,
wherein the sputtering target and the plasma source are directed to different sections of the peripheral region,
a sputter gas inlet configured to introduce a sputtering gas into the recipient, and
a reactive gas inlet and/or a further reactive gas inlet configured to introduce a reactive gas into the recipient,
wherein the holder is configured to rotate at a rotation speed from 30 to 0.5 seconds per rotation and the magnetron power station is configured to be operated at a magnetron power level (Pₘ) from 0.5 to 10 kW.

34. (canceled)

35. The vacuum process system according to claim 33, wherein the at least one plasma treatment station comprises an inductive plasma source or a capacitively coupled plasma source, and wherein the reactive gas inlet is configured to introduce the reactive gas directly into the at least one plasma treatment station.

36. The vacuum process system according to claim 35, wherein the at least one plasma treatment station is comprises a capacitively coupled HF-plasma source.

37. The vacuum process system according to claim 33, further comprising a noble gas supply, wherein the sputtering target is a silicon target, and the sputter gas inlet is connected to the noble gas supply.

38. The vacuum process system according to claim 33, further comprising a plasma emission monitor (PEM), wherein the plasma source comprises a plasma zone, and wherein the plasma emission monitor (PEM) is connected via an optical path of light to the plasma zone of the plasma source.

39. The vacuum process system according to claim 33, wherein the at least one plasma treatment station comprises a further magnetron sputter station comprising a further target.

40. The vacuum process system according to claim 39, wherein the further target is at least one of Si, SiO₂, Si₃N₄, Al, Al₂O₃, AlN, and a mixture thereof.

41. The vacuum process system according to claim 39, wherein the sputtering target is at least one of Al, Si, Ti, Zr, Hf, Nb, Ta, Ge respective oxides, nitrides er and a mixture thereof.

42. The vacuum process system according to claim 39, further comprising a separate reactive gas inlet configured to introduce a reactive gas into the further magnetron sputter station.

43. The vacuum process system according to claim 33, wherein the holder comprises a turntable holder defining a turntable holder plane and a central axis, and having a main surface, an outer circular ring and a plurality of substrate supports arranged along the outer circular ring on the main surface, wherein each of the plurality of substrate supports is oriented in a plane parallel to the turntable holder plane.

44. The vacuum process system according to claim 43, wherein the magnetron sputter station comprises a circular target and a static magnet arrangement, said magnet arrangement
being arranged in a magnet-arrangement plane (M) in parallel to the turntable holder plane; and
not being rotational symmetric.

45. The vacuum process system according to claim 44, wherein an area bordered by the magnet system can be separated along a line (K) in the magnet-arrangement plane (M) intersecting perpendicularly target axis (C) into an outer area (16) oriented away from the centre of the turntable and one inner area (17) oriented towards it,
where the outer area (16) is larger than the inner area (17).

46. The vacuum process system according to claim 45, wherein said magnet arrangement (11) is mirror-symmetric about a symmetry axis (A) in the magnet-arrangement plane (M), wherein the symmetry axis (A) intersects the central axis of the turntable holder.

47. The vacuum process system according to claim 44, wherein the target has a central target axis and is configured to rotate about the central target axis.

48. The vacuum process system according to claim 33, wherein the peripheral region comprises a cylindrical or cylinder-like multifaceted surface, a plurality of substrate supports is arranged along the cylindrical or cylinder-like multifaceted surface, and each of the plurality of substrate supports is oriented in a plane essentially parallel to the cylindrical or cylinder-like multifaceted surface.

49. The vacuum process system according to claim 33, comprising at least two magnetron sputter stations and at least one plasma treatment station which is not a magnetron sputter station, wherein each station comprises a plasma emission monitor to control a reactive process in the respective station.

50. The vacuum process system according to claim 45, wherein said magnet arrangement (11) is not mirror-symmetric.

51. The vacuum process system according to claim 42, wherein the reactive gas inlet is configured to introduce a reactive gas into the magnetron sputter station.
